(19) United States
(12) Patent Application Publication
(10) Pub. No.: US 2019/0259689 A1
(43) Pub. Date: Aug. 22, 2019

(54) Re-Routable Clip for Leadframe Based Product

(71) Applicant: Dialog Semiconductor (UK) Limited, London (GB)

(72) Inventors: Tung Ching Lui, Kirchheim/Teck (DE); Baltazar Canete, Waiblingen (DE); Melvin Martin, Fellbach (DE); Rajesh Subraya Aiyandra, Denkendorf (DE)

(21) Appl. No.: 15/899,049

(22) Filed: Feb. 19, 2018

(51) Int. Cl. H01L 23/495; H01L 23/498; H05K 1/02

(52) U.S. Cl. CPC H01L 23/49568; H01L 23/49582; H01L 23/4951; H01L 2924/1811; H01L 23/49838; H05K 1/0265; H01L 2224/05012; H01L 23/49816

(57) ABSTRACT

A method of fabricating an integrated circuit package having improved heat dissipation is described. A re-routable clip is provided having a central portion and a plurality of leads surrounding the central portion. A die is attached to an underside of the central portion of the re-routable clip. The die and the leads of the re-routable clip are attached to a substrate. The die and the leads are encapsulated with a mold compound wherein a top surface of the central portion of the re-routable clip is exposed by the mold compound. The substrate is connected to a printed circuit board wherein thermal pathways are formed 1) from the die downward to the substrate to the printed circuit board and 2) from the die upward to the re-routable clip and then downward through the leads to the substrate and to the printed circuit board.

### TECHNICAL FIELD This disclosure is related to leadframe based packages, and more particularly, to improved heat transfer in leadframe based packages.

### BACKGROUND

A leadframe (LF) based package such as QFN (Quad Flat No-Lead) is a plastic encapsulated package which is popular in many applications needing efficient power dissipation where form factor, weight, and thermal and electrical performance are critical aspects. An exposed die paddle provides excellent thermal performance enhancements which are ideal for high frequency and high power applications and are especially suited for wireless and handheld portable applications such as cell phones.

The electronic package design involves a very complicated manufacturing process. One of the important aspects is thermal management. The main objective for thermal management is to cool down the integrated circuit (IC) chip/die that is secured by heat distribution from the IC die/chip to the ambient. This can be done in many ways. Previously, packages were not required to deal with cooling since they had low power input and temperature. The situation has changed with increasing performance and reduced area for cooling. Now, thermal management is a critical aspect of electronic package design.

U.S. Pat. No. 8,039,951 (Kanth et al), U.S. Pat. No. 9,214,416 (Furnival), and U.S. Pat. No. 7,557,432 (Tang et al) and U.S. Patent Applications 2015/0200149 (Zhao et al), 2008/0117957 (do et al), and 2016/0148890 (Khan et al) disclose various methods of heat dissipation in packages.

### SUMMARY

It is the primary objective of the present disclosure to provide heat dissipation for an integrated circuit package.

It is another objective of the present disclosure to provide multiple pathways of heat dissipation for an integrated circuit package.

It is a further objective of the present disclosure to provide multiple pathways of heat dissipation for an integrated circuit package by incorporating a re-routable clip in the package.

It is yet another objective of the present disclosure to provide a method of fabricating an integrated circuit package having multiple pathways of heat dissipation by incorporating a re-routable clip in the package.

In accordance with the objectives of the present disclosure, a method of fabricating an integrated circuit package having improved heat dissipation is achieved. A re-routable clip is provided having a central portion and a plurality of leads surrounding the central portion. A die is attached to an underside of the central portion of the re-routable clip. The die and the leads of the re-routable clip are attached to a substrate. The die and the leads are encapsulated with an encapsulation material wherein a top surface of the central portion of the re-routable clip is exposed to ambient air by the encapsulation material. The substrate is connected to a printed circuit board wherein thermal pathways are formed 1) from the die downward to the substrate to the printed circuit board and 2) from the die upward to the re-routable clip and then downward through the leads to the substrate and to the printed circuit board.

Also in accordance with the objectives of the present disclosure, an integrated circuit package is achieved. A metal re-routable clip is provided having a central portion and clips leads surrounding the central portion wherein the clip leads are attached to a substrate. A die having a top and a bottom surface is attached at the top surface to an underside of the central portion of the re-routable clip and attached at the bottom surface to the substrate. A mold compound encapsulates the die, the substrate, and the re-routable clip except for a top surface of the central portion of the re-routable clip which is exposed to ambient air by the mold compound. The integrated circuit package is attached to a printed circuit board wherein thermal pathways are formed 1) from the die downward to the substrate to the printed circuit board and 2) from the die upward to the re-routable clip and then downward through the clip leads to the substrate and to the printed circuit board.

The substrate can be: a leadframe, a quad flat no-lead (QFN) package, a dual flat no-lead (DFN) package, a ball grid array, a package-based chip stack, a package on package, a 3D integrated die stack, a multi-chip package, a land grid array, or a system in package.

### BRIEF DESCRIPTION OF THE DRAWINGS

In the accompanying drawings forming a material part of this description, there is shown:

FIG. 1A is a cross-sectional representation of a leadframe package of the prior art.

FIG. 1B is a cross-sectional representation of a QFN leadframe package of the prior art.

FIG. 2 is a cross-sectional representation of a leadframe package of the prior art showing its heat dissipation path.

FIG. 3 is a cross-sectional representation of a leadframe package of a preferred embodiment of the present disclosure showing its heat dissipation paths.

FIGS. 4A-4F are isometric representations of steps in a process to fabricate a leadframe package in a preferred embodiment of the present disclosure.

FIGS. 5A and 5B are cross-sectional representations of two alternative connection methods in a preferred embodiment of the present disclosure.

FIG. 5C is a top view of the re-routable clip of the present disclosure.

FIG. 5D is a cross-sectional representation of a preferred embodiment of the present disclosure.

FIG. 6 is a cut-away isometric view of a completed QFN leadframe package in a preferred embodiment of the present disclosure.

FIGS. 7A-7D are isometric views of alternative QFN leadframe packages in preferred embodiments of the present disclosure.

FIGS. 8A-8H are cross-sectional representations of alternative leadframe packages in preferred embodiments of the present disclosure.

FIGS. 9A and 9B are graphical representations of temperature at the die center as a function of time for thermal simulations of both convention products and products according to the preferred embodiments of the present disclosure.

### DETAILED DESCRIPTION

In a leadframe based package, thermal design is closely related to the mounting possibilities on the board because of the direct contact between the printed circuit board (PCB) and the leads or die paddle of the QFN or Dual Flat No-Lead (DFN) package. Thermal design also influences the components near the package because of higher temperatures.

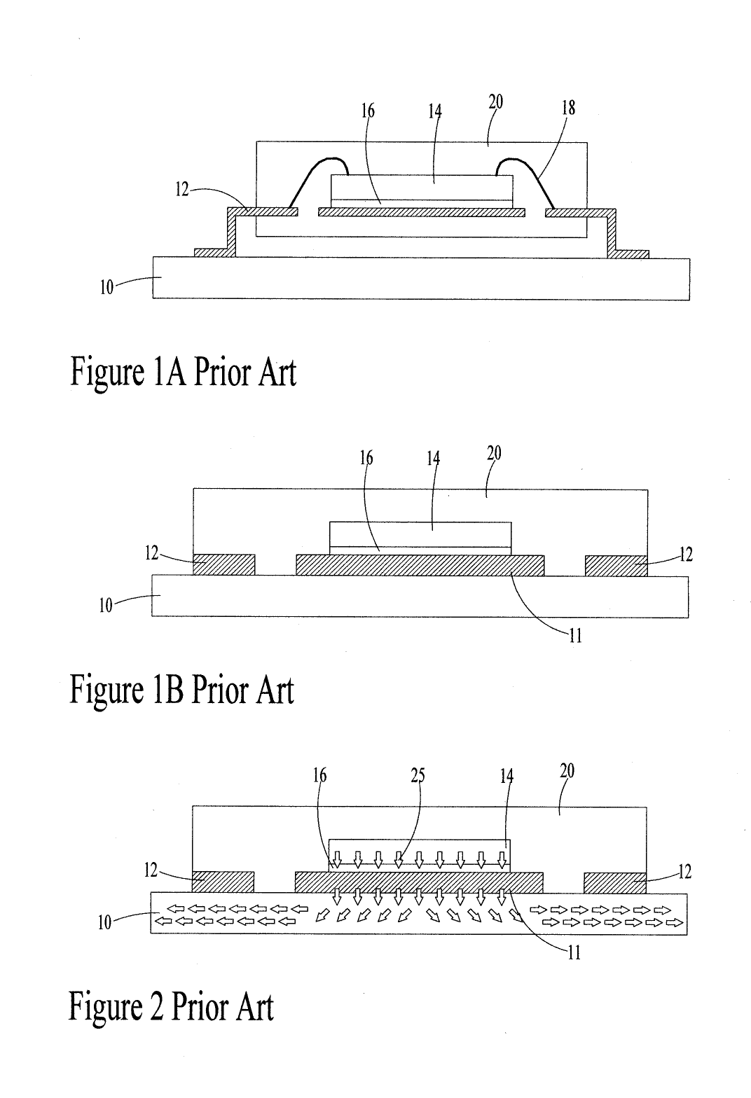

FIG. 1A illustrates a conventional leadframe package having a leadframe 12 mounted on a PCB 10. A die 14 is attached to the leadframe 12 using die attach adhesive 16. The die is connected to the leadframe by wire bonds 18. The die is encapsulated by molding 20. FIG. 1B illustrates a conventional QFN package having a leadframe 12 mounted on a PCB 10. A die 14 is attached to the die paddle 11 of the leadframe 12 using die attach adhesive 16. The die is encapsulated by molding 20.

Thermal design historically has meant finding out which components in the system generate the most heat and coupling them to a heat sink. However, with power systems shrinking and becoming more cost-sensitive, heat sinks have become a less attractive option. New designs use the PCB as a heat sink. The conventional QFN, for example, is a leadframe package which has an integrated die paddle on the bottom that offers a low resistance path to conduct heat out of the device. FIG. 2 illustrates the QFN of FIG. 1B, for example, showing the path 25 of heat from the die 14. The heat is conducted to a copper landing pad on the PCB through a solder joint, effectively turning the PCB into a heat sink.

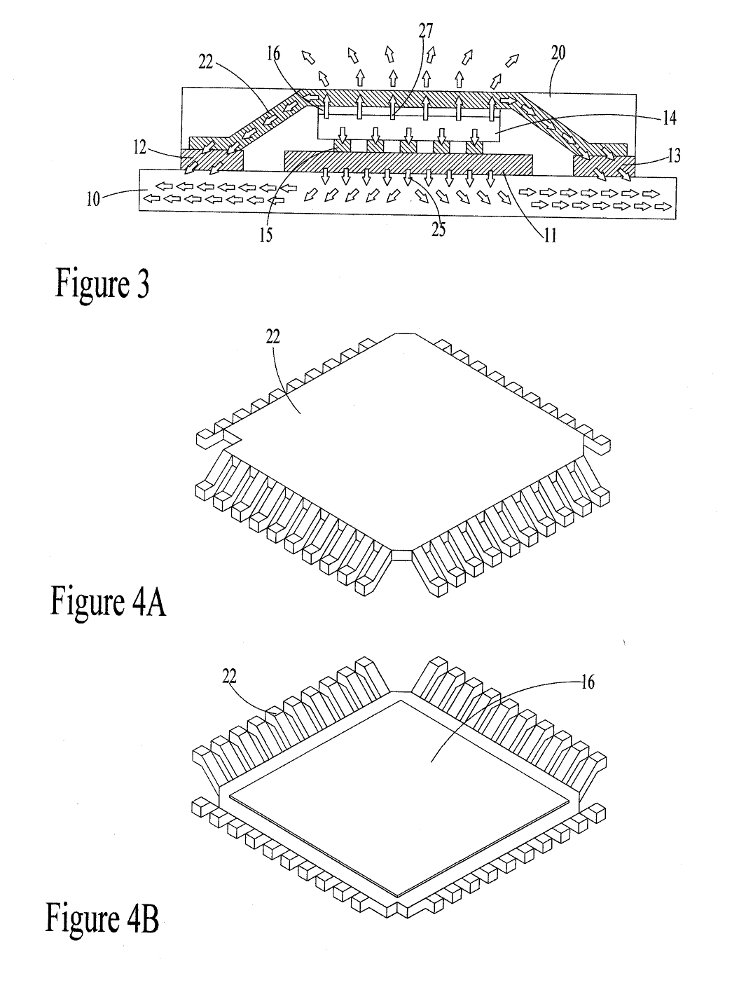

The present disclosure proposes to have a cavity down leadframe based package using a re-routable clip. As shown in FIG. 3, the IC chip/die 14 will be mounted on the re-routable clip 22 by die attach and/or a die attach film that provides excellent control uniformity of bond line thickness. Alternatively, the IC die/chip could be connected by metal pillars, bonding wires, or both. FIG. 3 illustrates the re-routable clip 22 which is exposed to the ambient air. In this novel package, the thermal paths include: (1) path 25 from die 14 to die paddle 11 of leadframe 12 and then to the underlying PCB 10 and (2) path 27 from die 14 to the re-routable clip 22 and then to peripheral leads 13 to the PCB 10 and also to the surrounding environment. With an extra heat dissipation path from the re-routable clip, the junction temperature of the QFN could be significantly reduced. Hence, the form factor and weight could be further reduced or the power level could be much higher.

To further optimize thermal performance, not only does the heat need to conduct through the die paddle to the PCB, it also must effectively transfer into the surroundings and away from the device to the ambient air. Therefore, the present disclosure is critical to ensuring robust thermal heat dissipation.

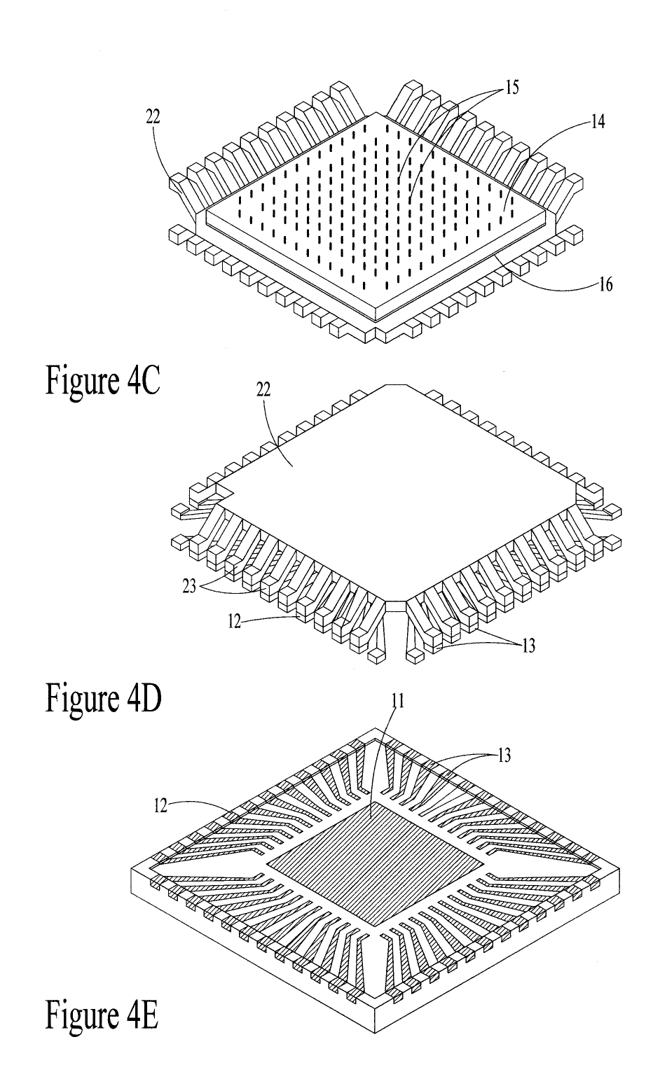

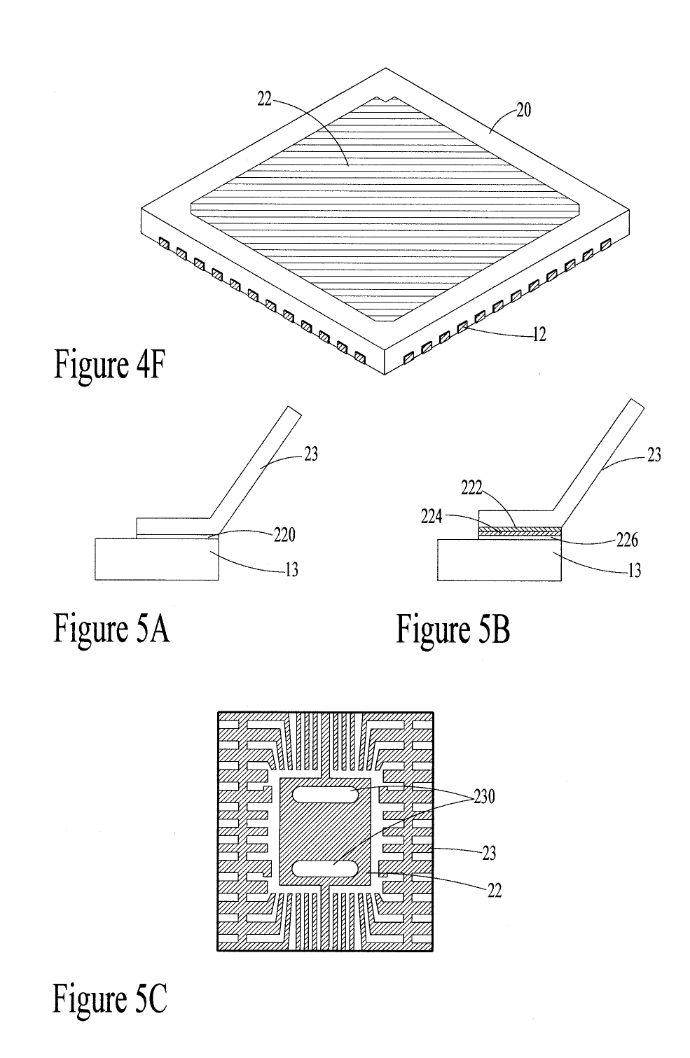

Referring now more particularly to FIGS. 4A-4F, a preferred embodiment of the present disclosure to manufacture a QFN package is described. The re-routable clip 22 is illustrated in FIG. 4A. The re-routable clip comprises a metal material. The geometry and material can be the same as the conventional leadframe for quad flat package (QFP) products or it can be tailor-made. A die attach material 16 is applied to the underside of the re-routable clip 22, as shown in FIG. 4B.

Metal pillars or connectors 15 are built on the IC chip/die 14. Then the assembly is pick and placed on the die paddle of re-routable clip 22 and mounted on the clip 22 by the die attach material 16, as shown in FIG. 4C.

The metal pillars or connectors 15 attach the IC chip/die to the die paddle 11 of the leadframe 12. Leads 23 of the re-routable clip 22 are attached to leads 13 of the leadframe, as shown in FIG. 4D, by soldering or a non-conductive adhesive. The re-routable clip 22 can have any number of contact pads/points with leadframe 12. FIG. 5A illustrates a lead 23 of the re-routable clip attached to lead finger 13 of the leadframe by a non-conductive adhesive 220. As shown in FIG. 5B, optionally, a dielectric layer 226 is formed on the lead fingers 13 for short circuit prevention. Copper 224 is shown contacting solder 222. The leads 23 on re-routable clip 22 can be fully used or selectively trimmed and attached on the bottom leadframe 12.

All components are encapsulated by a mold compound or other encapsulation material 20, as shown in bottom view in FIG. 4E and in top view in FIG. 4F. As the geometry is similar to the conventional leadframe, molding compound 20 flows between the leads to form a locking system to prevent delamination. If necessary, openings or slots 230, as shown in FIG. 5C, on the die paddle of re-routable clip 22 could be employed to interlock the mold compound and the re-routable clip to prevent any delamination. From the package top, the re-routable clip 22 is exposed to the ambient environment, as shown in FIG. 4F.

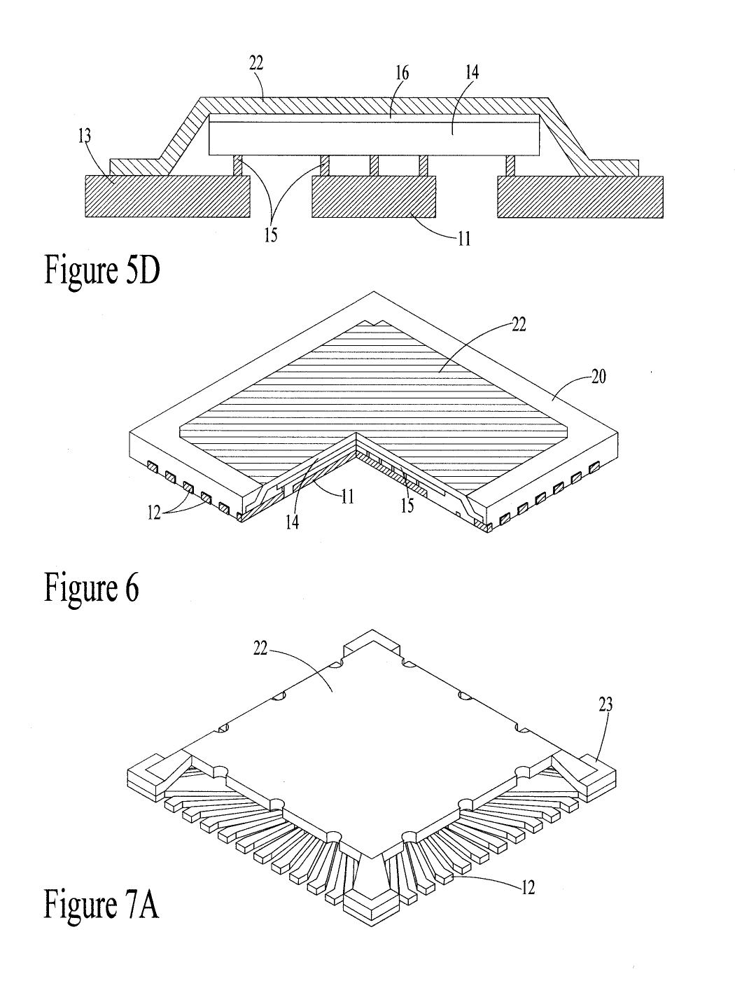

FIG. 6 shows a cut-away view of a QFN package of the present disclosure. In the package, the IC die/chip 14 is thermally and/or electrically connected by connector 15 to conductive features of the leadframe 12 such as die paddle 11 and/or lead fingers 13. In FIG. 6, it can be seen that the IC die/chip is connected by connectors 15 to the die paddle 11 of the leadframe 12. FIG. 5D illustrates connection of the IC die/chip 14 by connectors 15 to both the die paddle 11 and lead fingers 13.

The conductive feature 11 is coupled to a circuit board such as a PCB (not shown in FIG. 6). A bottom surface of IC die/chip 14 is contacted to the re-routable clip 22 by epoxy, glue, die attach or die attach film 16.

Mold compound 20 encapsulates the QFN package. Re-routable clip 22, IC die/chip 14, leadframe 12, conductive feature 11 and metal pillars 15 are completely embedded within mold compound 20. Re-routable clip 22 is partially encapsulated by mold compound 20. The top surface of re-routable clip 22 is not covered by mold compound 20 and it is co-planar with a top surface of the mold compound 20. One method is to over-mold; that is, the exposed part of re-routable clip will not be molded. Another method is to mold the entire package and then grind away the extra mold until the top surface of the re-routable clip is exposed to the ambient.

The key feature of the present disclosure is the dual pathway for heat dissipation from the IC chip/die downward to the die paddle to the underlying PCB and upward to the overlying re-routable clip from which the heat dissipates to the ambient or downward through the re-routable clip to the leadframe to the underlying PCB. These thermal paths are illustrated by the arrows 25 and 27 in FIG. 3 for a sample QFN.

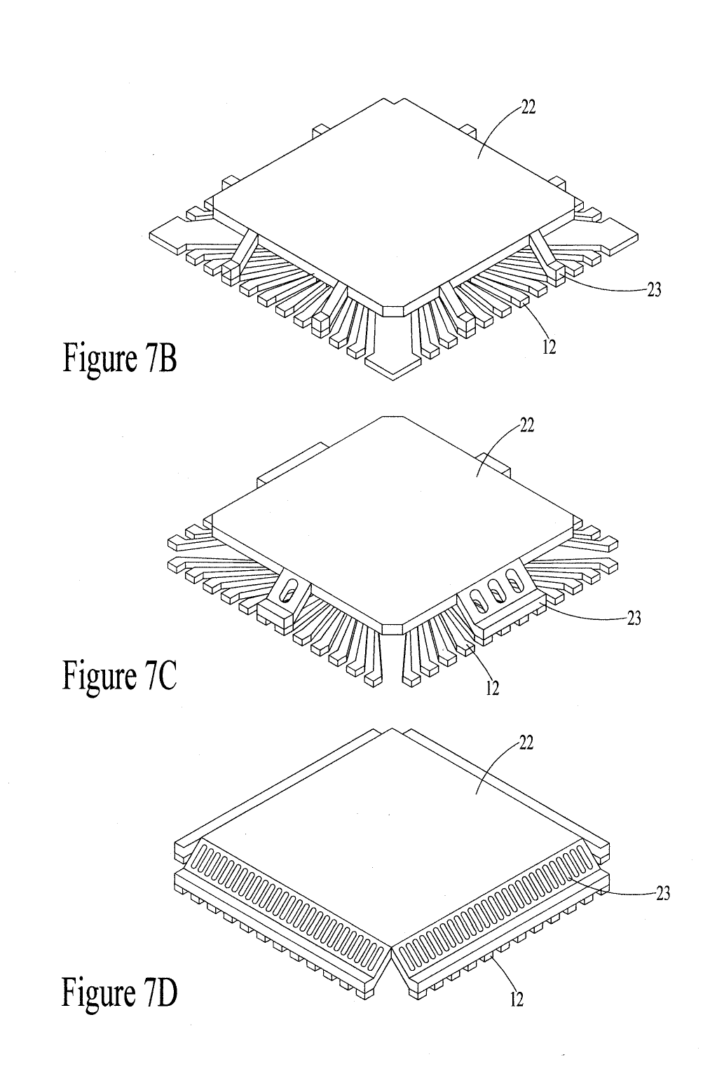

FIG. 7A-7D illustrate variations of shape of the re-routable clip 22 and the leadframe 12 for a QFN, showing some of the leads 23 have been trimmed in various ways. In FIG. 7D, all the leads 23 on the re-routable clip 22 are shorted/connected.

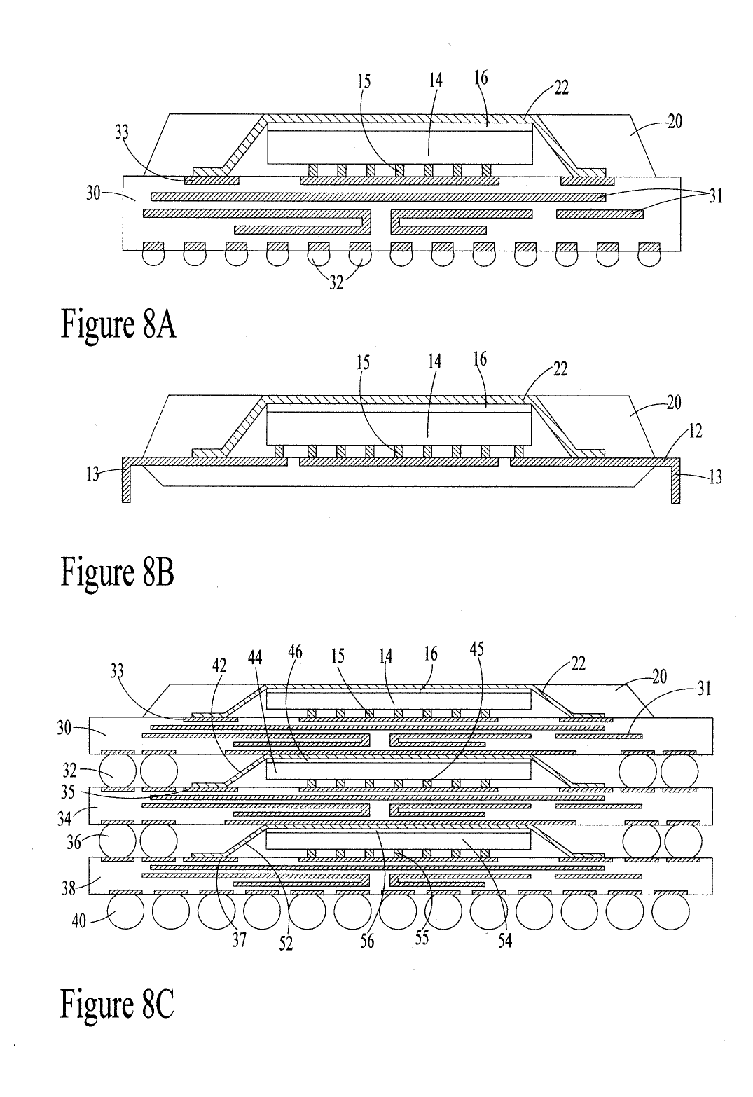

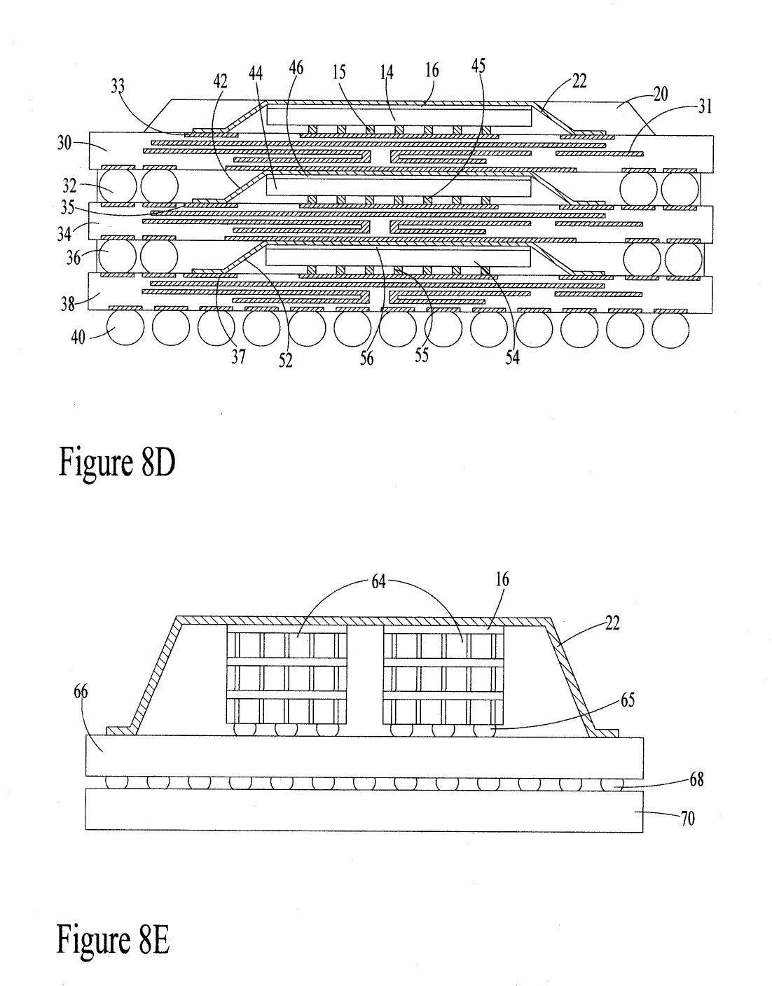

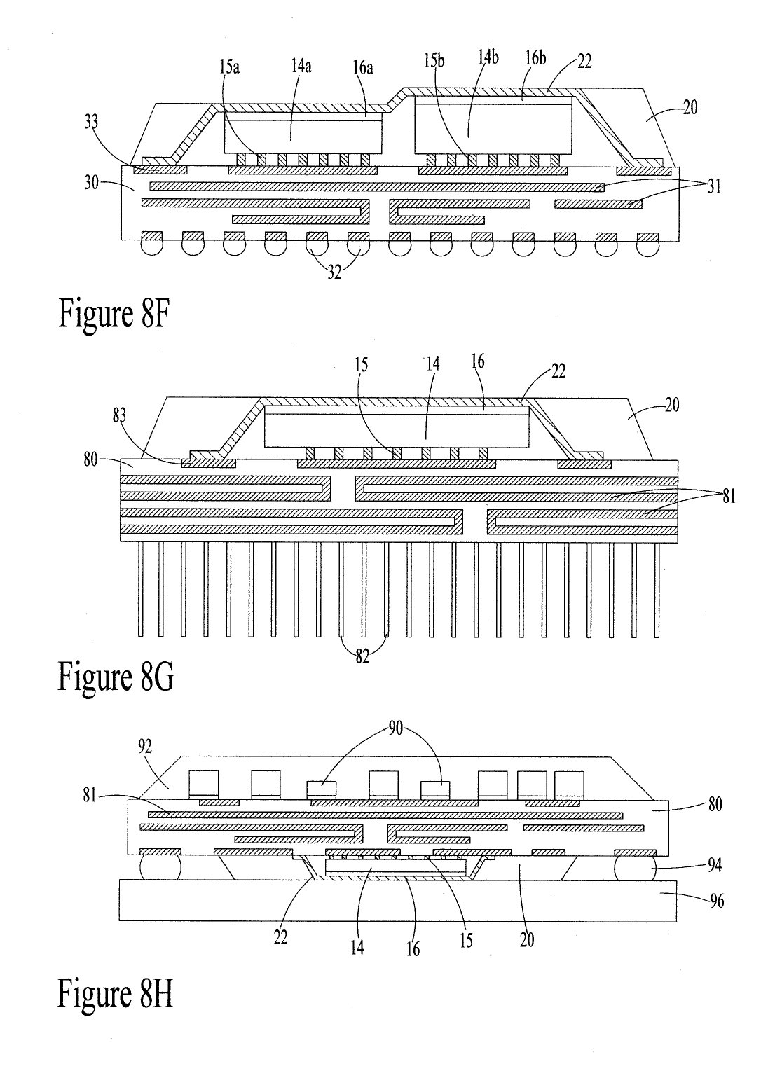

The dual pathway heat dissipation through re-routable clip can also be used in other types of packages, illustrated in FIGS. 8A-8H. FIG. 8A illustrates a ball grid array (BGA) package including substrate 30 with redistribution layers 31 and solder balls 32. IC chip/die 14 is attached to re-routable clip 22 through die attach 16. The re-routable clip 22 is further connected to pads 33 on the substrate 30 by soldering, for example. A PCB, not shown, will be attached to the BGA package by solder balls 32. The top surface of re-routable clip 22 is exposed to the ambient.

FIG. 8B illustrates a leadframe package. IC chip/die 14 is attached to re-routable clip 22 through die attach 16. The re-routable clip 22 is further connected to leadframe 12 by soldering or non-conductive adhesive. Mold compound 20 encapsulates the IC chip/die, re-routable clip 22 except for the top surface, and leadframe 12 except for fingers 13 that will connect to a PCB, not shown.

FIG. 8C illustrates a package-based chip stack. IC chip/die 14 is attached to re-routable clip 22 through die attach 16. The re-routable clip 22 is further connected to pads 33 on the substrate 30 by soldering, for example. Substrate 30 includes redistribution layers 31 and solder balls 32. Additional dies 44 and 54 are attached to re-routable clips 42 and 52, respectively. These clips 42 and 52 are further connected to pads 35 and 37 on substrates 34 and 38, respectively. Solder balls 32 connect substrate 30 to substrate 34. Solder balls 36 connect substrate 34 to substrate 38. Solder balls 40 will connect substrate 38 to an additional substrate or to a PCB, not shown. Only the topmost die is encapsulated by molding compound 20. The top surface of topmost re-routable clip 22 is exposed to the ambient air.

FIG. 8D illustrates a package on package. This package is similar to the package in FIG. 8C except that all the chips in FIG. 8 7D are encapsulated with mold compound. The top surface of topmost re-routable clip 22 is exposed to the ambient.

FIG. 8E illustrates a 3D integrated chip stack. Interposer 66 is connected to PCB 70 by solder balls 68. Die stacks 64 are attached to re-routable clip 22 by die attach 16 and are attached to interposer 66 by connectors 65. Re-routable clip 22 is also attached to interposer 66 by soldering, for example. Mold compound may encapsulate the die stacks, but it is not necessary.

FIG. 8F illustrates a multi-chip package. IC chip/dies 14a, 14b are attached to re-routable clip 22 by die attach material 16a, 16b, respectively, for example. The dies 14a, 14b are also attached to substrate 30 having redistribution layers 31 therein by copper pillars 15a, 15b, for example. The re-routable clip 22 is further connected to pads 33 on the substrate 30. Mold compound 20 encapsulates the IC chip/dies and re-routable clip 22 except for its top surface. Solder balls 32 on the substrate 30 attach to a PCB, not shown.

FIG. 8G illustrates a land grid array package. IC chip/die 14 is attached to re-routable clip 22 by die attach 16 and is connected using copper pillars 15, for example, to substrate 80 having redistribution layers 81. The re-routable clip 22 is further connected to substrate 80 by soldering to metal pads 83, for example. Mold compound 20 encapsulates the IC chip/die and re-routable clip 22 except for the top surface of the clip. A PCB, not shown, will be attached to the LGA package by landing pads 82.

FIG. 8H illustrates a system in package (SIP). IC chip/die 14 is attached to re-routable clip 22 and is connected using copper pillars 15, for example, to substrate 80 having redistribution layers 81. The re-routable clip 22 is further connected to a topmost redistribution layer 81 on substrate 80. Mold compound 20 encapsulates the IC chip/die and re-routable clip 22 except for the top surface of the clip. Passive components 90 are connected on an opposite side of the substrate 80 and encapsulated in mold compound 92. A PCB 96 is attached to the top surface of the re-routable clip 22 by soldering or conductive/non-conductive adhesive and to the substrate 80 by solder balls 94.

In FIG. 8H, the re-routable clip 22 is attached directly to the PCB 96. The two heat dissipation paths here are: 1) The heat is generated by the die 14 and flows to the connectors 15, substrate 80, passive components 90, and back to connector 94 and finally to the PCB 96, and 2) The heat is generated by the die 14 and flows to the die attach 16, re-routable clip 22 and finally to the PCB 9. The heat will be removed mainly by path 2 as the connectors 15 between the substrate 80 and die 14 are very efficient. However, path 1 would provide a certain amount of heat dissipation effect.

Thermal simulations were carried out to prove the heat dissipation effect of the re-routable clip of the present disclosure. Product A is a leadframe-based 32 flip-chip quad flat no lead (FC-QFN) package. The original package outline design (POD) is: die size=2.7×4.1×0.15 mm³ and the package size=5.0×7.0×0.577 mm³. The modified design uses the re-routable clip of the present disclosure. The package size of the modified package is 5.0×7.0×0.47 mm³. The total power dissipation is 1.843 W in four hot spot areas and the package is mounted on a 4-layer (4L) Joint Electron Device Engineering Council (JEDEC) standard board operating at an ambient temperature of 65° C. Table 1 illustrates the thermal simulation results.

TABLE 1

| | | Product A | |
|---|---|---|---|
| | Product A (original) | (modified) | Unit |
| With re-routable clip | No | Yes | |
| package size | 5.0 × 7.0 × 0.577 | 5.0 × 7.0 × 0.47 | mm³ |
| junction | 124.0 | 117.6 | ° C. |
| temperature | | | |
| Theta-JA | 32.0 | 28.5 | ° C./W |

As can be seen in Table 1, the junction temperature of Product A without the re-routable clip is 124.0° C. which is close to the maximum allowable junction temperature (i.e. 125° C.). The junction temperature of Product A with the re-routable clip is 117.6° C. The difference is 6.4° C. The thermal contours indicate that heating in the original Product A was localized or trapped inside the device. However, in the modified Product A, heat progressed towards the PCB and the top surface. This is due to the parallel combination of die paddle and re-routable clip.

A second thermal simulation was carried out from a customer in 2015. For the Product C design, the die size is 2.6×4.2×0.28 mm³ and the package size is 5.0×6.0×0.85 mm³. The total power dissipation is 2.63 W applied on 8 hot spot locations with a JEDEC 4L PCB. The simulation is operated at an ambient temperature of 65° C. and the maximum allowable junction temperature is 125° C. The original Product C showed a junction temperature of 140.9° C. The modified Product C with the re-routable clip had a junction temperature of 137.4° C. The difference is 4.6° C. The thermal contours indicated that the heat dissipation at the hot spot was concentrated on certain leads in the package without the re-routable clip. After applying the re-routable clip, the heat was evenly spread out and the hot spot was minimized.

A third thermal simulation was performed using Product C (34 FC-QFN) and another design Product B (30 FC-QFN). The two projects were mounted together on an application PCB. The die size of Product C was 2.6×4.2×0.28 mm³ and the die size of Product B was 2.6×5.04×0.28 mm³. The package size of Product C was 5.0×6.0×0.85 mm³ and the package size of Product B was 4.5×7.0×0.85 mm³. The total power dissipation on Product C was 2.63 W and on Product B, 2.28 W. The modified design used the re-routable clip of the present disclosure. The simulation was operated at an ambient temperature at 65° C. and the maximum allowable junction temperature was 125° C. Table 2 illustrates the simulation results for Product B and Product C.

TABLE 2

| | Original | Original | Modified | Modified | |
|---|---|---|---|---|---|
| | Product B | Product C | Product B | Product C | Units |
| With re- | No | No | Yes | Yes | |
| routable clip | | | | | |
| Total Power | 2.28 | 2.63 | 2.28 | 2.63 | W |
| Junction | 103.2 | 114.3 | 99.1 | 108.2 | ° C. |
| temperature | | | | | |
| Theta-JA | 16.8 | 18.7 | 15.0 | 16.4 | ° C./W |
| Difference | Ref. | Ref. | 10.7 | 12.2 | % |

The original design of Product B and Product C had junction temperatures of 103.2° C. and 114.3° C. while Product B and Product C with re-routable clip had junction temperatures of 99.1° C. and 108.2° C. All electronics are trending in the direction of higher power densities which require very uniform temperatures across the product while heating-up and cooling-down as quickly and as consistently as possible.

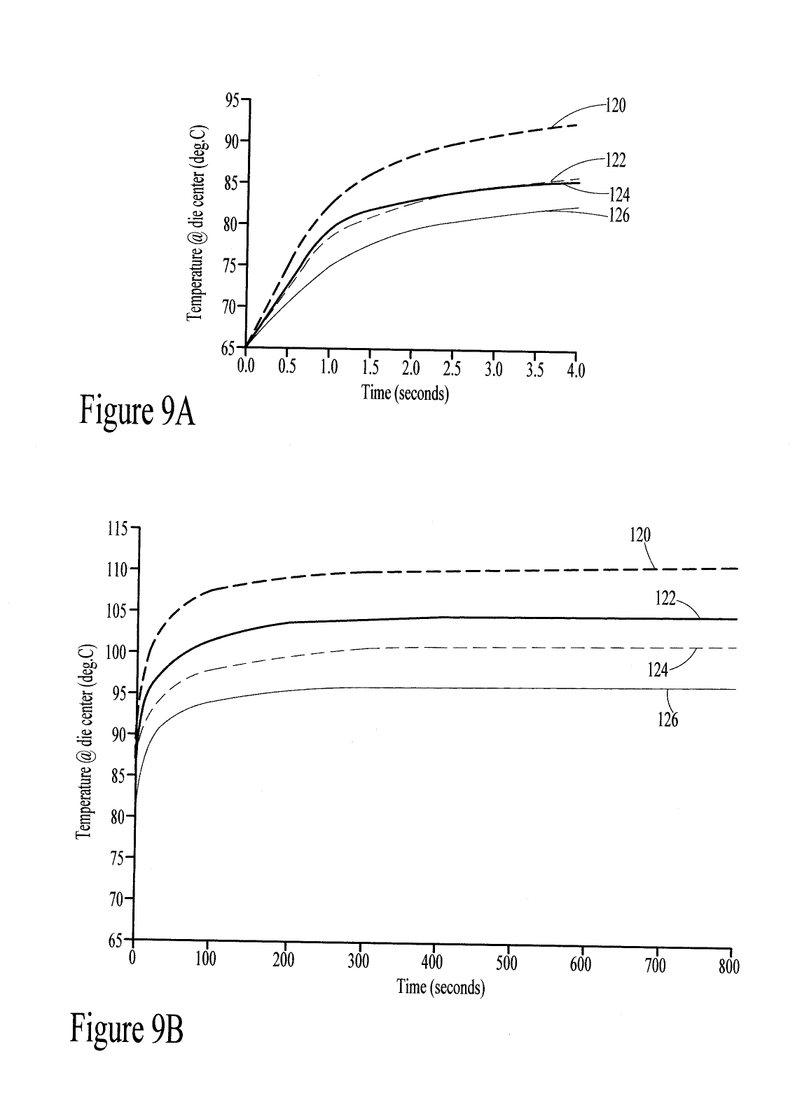

The temperature rise is illustrated by the curves in FIGS. 8A and 8B showing the temperature differences between the package with and without the re-routable clip of the present disclosure. FIG. 9A illustrates the first four seconds of run time. FIG. 9B illustrates time 0-800 seconds. The temperatures were measured at the die center. Curve 120 illustrates Product C without the clip, 122, Polo with the clip, 124, Product B without the clip, and 124, Product B with the clip. For Product C, the difference is 4° C. and for Polo, the difference is 6° C.

The process of the present disclosure provides an integrated circuit package having multiple thermal pathways including: (1) from the die to an underlying substrate or frame and then to the underlying PCB and (2) from the die to the re-routable clip and then to the underlying substrate or frame and then to the underlying PCB and from the re-routable clip to the surrounding environment. With an extra heat dissipation path from the re-routable clip, the junction temperature of the package could be significantly reduced. Hence, the form factor and weight of the package could be further reduced or the power level could be much higher. In the process of the present disclosure, the leadframe package and the PCB do not need to be re-designed for thermal enhancement. The re-routable clip can be attached to any or all lead fingers of the leadframe if necessary to expand the heat dissipation path as much as possible. The lead fingers 12 can be used as input and output pins as well as heat dissipation paths.

Although the preferred embodiment of the present disclosure has been illustrated, and that form has been described in detail, it will be readily understood by those skilled in the art that various modifications may be made therein without departing from the spirit of the disclosure or from the scope of the appended claims.

1. A method of fabricating an integrated circuit package comprising:
providing a re-routable clip having a central portion and a plurality of leads on all sides of said central portion;
attaching a die to an underside of said central portion of said re-routable clip;
connecting said die and said leads of said re-routable clip to a substrate;
encapsulating said die and said leads with an encapsulation material wherein a top surface of said central portion of said re-routable clip is exposed to ambient air by said encapsulation material; and
connecting said substrate to a printed circuit board wherein thermal pathways are formed 1) from said die downward to said substrate to said printed circuit board and 2) from said die upward to said re-routable clip and then downward through said leads to said substrate and to said printed circuit board.

2. The method according to claim 1 wherein said substrate is chosen from the group containing: a leadframe, a quad flat no-lead (QFN) package, a dual flat no-lead (DFN) package, a ball grid array, a package-based chip stack, a package on package, a 3D integrated die stack, a multi-chip package, a land grid array, and a system in package.

3. The method according to claim 1 wherein said re-routable clip comprises metal.

4. The method according to claim 1 wherein said attaching said die to an underside of said central portion of said re-routable clip is by die attach.

5. The method according to claim 1 wherein said die is attached to said substrate by connectors or metal pillars.

6. The method according to claim 1 wherein said leads are connected to said substrate by solder or by non-conductive adhesive.

7. The method according to claim 1 wherein said encapsulation material comprises a mold compound.

8. An integrated circuit package having improved heat dissipation comprising:
a metal re-routable clip having a central portion and leads on all sides of said central portion wherein said leads are attached to a substrate;
a die having a top and a bottom surface attached at said top surface to an underside of said central portion of said re-routable clip and attached at said bottom surface to said substrate;
wherein an encapsulation material encapsulates said die and said leads and wherein a top surface of said central portion of said re-routable clip is exposed to ambient air by said encapsulation material; and
said integrated circuit package attached to a printed circuit board wherein thermal pathways are formed 1) from said die downward to said substrate to said printed circuit board and 2) from said die upward to said re-routable clip and then downward through said leads to said substrate and to said printed circuit board.

9. The package according to claim 8 wherein said substrate is chosen from the group containing: a leadframe, a quad flat no-lead (QFN) package, a dual flat no-lead (DFN) package, a ball grid array, a package-based chip stack, a package on package, a 3D integrated die stack, a multi-chip package, a land grid array, and a system in package.

10. The package according to claim 9 wherein said re-routable clip comprises metal.

11. The package according to claim 9 wherein said attaching said die to an underside of said central portion of said re-routable clip is by die attach.

12. The package according to claim 9 wherein said die is attached to said substrate by connectors or metal pillars.

13. The package according to claim 9 wherein said leads are connected to said substrate by solder or by non-conductive adhesive.

14. The package according to claim 9 wherein said encapsulation material comprises a mold compound.

15. An integrated circuit package having improved heat dissipation comprising:
a metal re-routable clip having a central portion and leads on all sides of said central portion wherein at least some of said leads are attached to a leadframe;
a die having a top and a bottom surface attached at said top surface to an underside of said central portion of said re-routable clip and attached at said bottom surface to said leadframe;
wherein an encapsulation material encapsulates said die and said leads and wherein a top surface of said central portion of said re-routable clip is exposed to ambient environment by said encapsulation material; and
said integrated circuit package attached to a printed circuit board wherein thermal pathways for heat dissipation are formed 1) from said die downward to said substrate to said printed circuit board and 2) from said die upward to said re-routable clip and to an ambient or then downward through said leads to said leadframe and to said printed circuit board.

16. The package according to claim 15 wherein said re-routable clip comprises metal.

17. The package according to claim 15 wherein said die is attached is attached by connectors or metal pillars to a die paddle and/or leads of said leadframe.

18. The package according to claim 15 wherein said leads are connected to said leadframe by solder or by non-conductive adhesive.

19. The package according to claim 15 wherein said encapsulation material comprises a mold compound.
